(19) United States
(12) Patent Application Publication
(10) Pub. No.: US 2025/0315568 A1
(43) Pub. Date: Oct. 9, 2025

(54) HARDWARE CONFIGURATION AND DESIGN BASED ON ENVIRONMENTAL IMPACT

(71) Applicant: INTERNATIONAL BUSINESS MACHINES CORPORATION, ARMONK, NY (US)

(72) Inventors: KHAALID PERSAUD JUGGAN MCMILLAN, HAVERSTRAW, NY (US); JOHN S. WERNER, FISHKILL, NY (US); FRANKLIN GURNEY, RHINEBECK, NY (US); DUSTIN DEMETRIOU, HYDE PARK, NY (US); ANDREW C. M. HICKS, HIGHLAND, NY (US); KYLE INDUKUMMAR GIESEN, PITTSBORO, NC (US); CHRISTOPHER V DEROBERTIS, HOPEWELL JUNCTION, NY (US)

(21) Appl. No.: 18/630,350

(22) Filed: Apr. 9, 2024

(51) Int. Cl. G06F 30/20

(52) U.S. Cl. CPC G06F 30/20

(57) ABSTRACT

Hardware configuration and design based on environmental impact, including: receiving data encoding a system design comprising a plurality of components; calculating, based on the data, one or more environmental impact metrics; and validating the system design by comparing the one or more environmental impact metrics to one or more corresponding thresholds.

### BACKGROUND

The present disclosure relates to methods, apparatus, and products for hardware configuration and design based on environmental impact. Hardware design and manufacturing involves building systems while considering multiple factors that may change depending on the particular decisions made. It may be difficult to determine the impact on these decisions on various environmental factors and the overall environmental footprint of the system. Moreover, it may be difficult do determine how changes to the system will affect compliance with internal or external rules and regulations relating to sustainability and environmental impact. Accordingly, it may be beneficial to evaluate the environmental impact of a system during development.

### SUMMARY

According to embodiments of the present disclosure, various methods, apparatus and products for hardware configuration and design based on environmental impact are described herein. In some aspects, hardware configuration and design based on environmental impact includes receiving data encoding a system design comprising a plurality of components; calculating, based on the data, one or more environmental impact metrics; and validating the system design by comparing the one or more environmental impact metrics to one or more corresponding thresholds. This provides the advantage of enforcing environmental impact considerations during initial system design. In some aspects, an apparatus may include a processing device; and memory operatively coupled to the processing device, wherein the memory stores computer program instructions that, when executed, cause the processing device to perform this method. In some aspects, a computer program product comprising a computer readable storage medium may store computer program instructions that, when executed, perform this method.

In some aspects, this method may include providing, in response to the system design failing validation, one or more recommended modifications to the system design. This provides the advantage of facilitating modification of the system design so as to pass validation based on the environmental impact metrics.

In some aspects, this method may include modifying, in response to the system failing validation, based on at least one of the one or more environmental impact metrics, at least one of the one or more corresponding thresholds. This provides the advantage of adjusting component environmental impact thresholds that may cause validation to fail while preserving limitations on the system design as a whole.

In some aspects, validating the system design may further include applying one or more regional restrictions to the plurality of components. This provides the advantage of enforcing additional restrictions on component inclusion during system design that may be relevant to environmental or other considerations.

### BRIEF DESCRIPTION OF THE DRAWINGS

FIG. 1 sets forth a diagram of an example computing environment for hardware configuration and design based on environmental impact in accordance with some embodiments of the present disclosure.

FIG. 2 sets forth a flowchart of an example method for hardware configuration and design based on environmental impact in accordance with some embodiments of the present disclosure.

FIG. 3 sets forth a flowchart of another example method for hardware configuration and design based on environmental impact in accordance with some embodiments of the present disclosure.

FIG. 4 sets forth a flowchart of another example method for hardware configuration and design based on environmental impact in accordance with some embodiments of the present disclosure.

FIG. 5 sets forth a flowchart of another example method for hardware configuration and design based on environmental impact in accordance with some embodiments of the present disclosure.

### DETAILED DESCRIPTION

Hardware design and manufacturing involves building systems while considering multiple factors that may change depending on the particular decisions made. It may be difficult to determine the impact on these decisions on various environmental factors and the overall environmental footprint of the system. Moreover, it may be difficult to determine how changes to the system will affect compliance with internal or external rules and regulations relating to sustainability and environmental impact. Accordingly, it may be beneficial to evaluate the environmental impact of a system during development.

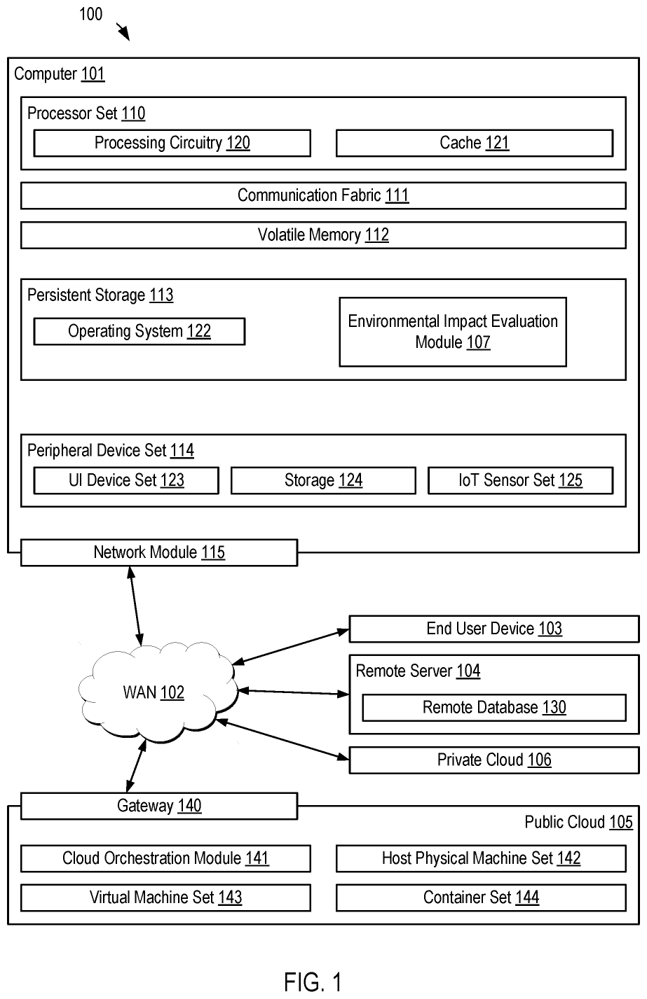

With reference now to FIG. 1, shown is an example computing environment according to aspects of the present disclosure. Computing environment 100 contains an example of an environment for the execution of at least some of the computer code involved in performing the various methods described herein, such as the environmental impact evaluation module 107. In addition to the environmental impact evaluation module 107, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 107, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 121 and the other storage media discussed below. The program instructions, and associated data, are accessed by processor set 110 to control and direct performance of the computer-implemented methods. In computing environment 100, at least some of the instructions for performing the computer-implemented methods may be stored in block 107 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 107 typically includes at least some of the computer code involved in performing the computer-implemented methods described herein.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database), this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the computer-implemented methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

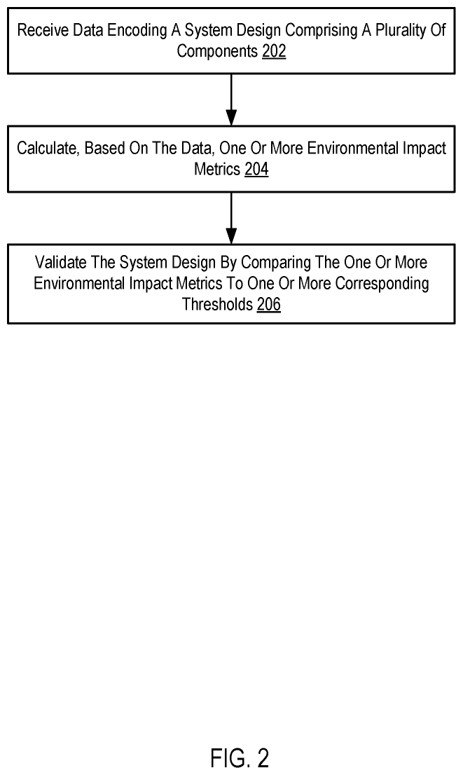

For further explanation, FIG. 2 sets forth a flowchart of an example method of hardware configuration and design based on environmental impact in accordance with some embodiments of the present disclosure. The method of FIG. 2 may be performed, for example, by the environmental impact evaluation module 107 described above. As an example, the environmental impact evaluation module 107 may be a component of, or used in conjunction with, computer aided design (CAD) software for designing components of a computing device or associated devices. The method of FIG. 2 includes receiving 202 data encoding a system design comprising a plurality of components. The data encoding the system design may include data for CAD software or other software as can be appreciated. As an example, the system design may include designs for mechanical components for housing electrical components, including chassis, cases, racks, enclosures, and the like. As another example, the system design may include designs for electrical components, including electrical traces or connections, functional electrical components such as chips or circuits, and the like. In some embodiments, the data encoding the system design may encode the shape or dimensions of the various components, interconnections between the various components in an assembled system, materials for the various components, and the like. In some embodiments, receiving 202 the data encoding the system design may include opening or otherwise accessing one or more files encoding the system design.

The method of FIG. 2 also includes calculating 204, based on the data, one or more environmental impact metrics. The one or more environmental impact metrics describe the environmental impact of the system design encoded in the received 202 data. In some embodiments, the one or more environmental impact metrics may reflect the environmental impact in assembling or manufacturing the system design and/or using the system design after manufacture. In some embodiments, the one or more environmental impact metrics may include a carbon footprint metric as a calculated value reflecting an amount of carbon emissions resulting from the system design. In some embodiments, the carbon footprint metric may be calculated using a function such as a weighted function whereby weights are applied to one or more variables or data points. For example, in some embodiments, the carbon footprint metric for a particular component of the system design may be calculated based on an amount of materials in a given component, a geographic location from where component materials or the component itself may be acquired, efforts required to process materials for the given component, an amount of like components in the system, and the like. In some embodiments, where particular components may be acquired or sourced from multiple regions, a user may select (e.g., via the design software) a particular region from which the components should be acquired for the purposes of calculating the carbon footprint metric. In some embodiments, the one or more environmental impact metrics may include amounts of materials in the system design. For example, the one or more environmental impact metrics may include amounts of particular materials or amounts of materials in particular classifications of materials (e.g., rare earth metals, non-biodegradable plastics, etc.).

In some embodiments, the one or more environmental impact metrics may be calculated on a per-component basis. In other words, for each component of the system design, one or more environmental impact metrics (e.g., component environmental impact metrics) may be calculated. In some embodiments, the one or more environmental impact metrics may be calculated on a per-system basis. In other words, at least a subset of the one or more environmental impact metrics may reflect the environmental impact of the system as a whole (e.g., a total environmental impact metric). In some embodiments, a component may include multiple sub-components. Accordingly, in some embodiments, a per-component environmental impact metric may be calculated as a function of the environmental impact metrics for the various sub-components of that component.

In some embodiments, environmental impact metrics may be calculated on both a per-component and per-system basis. For example, a per-system environmental impact metric may be calculated as a function of the per-component environmental impact metrics (e.g., as a sum, as a sum plus additional environmental impact due to packaging, distribution, or assembly). In some embodiments, the one or more environmental impact metrics for a given component may be calculated as a function of a mechanical contribution to the environmental impact metric and an electrical contribution to the environmental impact metric. A mechanical contribution is the amount or degree to which the mechanical subcomponents of a given component (e.g., structural or mechanical subcomponents) affect the environmental impact metric. An electrical contribution is the amount or degree to which the electrical subcomponents of a given component (e.g., traces, functional electrical subcomponents such as circuits or chips) affect the environmental impact metric.

The method of FIG. 2 also includes validating 206 the system design by comparing the one or more environmental impact metrics to one or more corresponding thresholds. In some embodiments, the one or more corresponding thresholds may include a per-system threshold (e.g., a total environmental impact threshold) for a particular environmental impact metric (e.g., a per-system carbon footprint metric). In some embodiments, the one or more corresponding thresholds may include one or more per-component thresholds for a particular environmental impact metric (e.g., a component environmental impact threshold). In some embodiments, the per-component thresholds may be different for each component. For example, assuming a system having components A, B, and C, the one or more corresponding thresholds may include a per-system carbon footprint metric threshold and different carbon footprint thresholds for each of components A, B, and C. In some embodiments, a same per-component thresholds may be applied to each component (e.g., such that no single component may have a particular environmental impact threshold exceeding the per-component threshold).

As is set forth above, validating 206 the system design includes comparing the one or more environmental impact metrics to the one or more corresponding thresholds. In some embodiments, the system design may be validated where each of the one or more environmental impact metrics falls below the one or more corresponding thresholds. In some embodiments, the one or more corresponding thresholds may be predefined. In some embodiments, one or more of the one or more corresponding thresholds may be dynamically calculated based on various data points. Continuing with the example above, a system design having components A, B, and C may be validated where the per-system environmental impact metrics fall below the corresponding per-system thresholds and where the per-component environmental impact metrics for each component A, B, and C falls below their respective per-component thresholds. Conversely, where an environmental impact metric exceeds the corresponding threshold, the system design may fail validation.

In some embodiments, validating 206 the system design may be performed in response to a variety of events. For example, in some embodiments, validating 206 the system design may be repeatedly performed (e.g., at a predefined interval) while the system design is open for viewing and/or editing in some design software. As another example, in some embodiments, validating 206 the system design may be performed in response to a command or user input indicating that the system design should be validated. As a further example, in some embodiments, validating 206 the system design may be performed in response to a command to save, export, or perform some other action with respect to the data encoding the system design. Validating 206 the system design may also be performed in response to other events as can be appreciated.

Various actions may be taken depending on whether the system design fails or passes validation. For example, in some embodiments, a warning may be presented to a user (e.g., via the design software accessing the data encoding the system design) indicating that the system design fails validation while a notification indicating successful validation may be presented when the system design passes validation. As another example, in some embodiments, various actions may be prevented or restricted where a system design fails validation, such as saving, exporting, entering manufacturing or production, and the like.

The approaches set forth above allow for environmental impact considerations to be taken into account during system design, enforcing particular limitations on various environmental impact metrics on a per-system and/or per-component basis. This ensures that a system design conforms to environmental impact and/or sustainability goals.

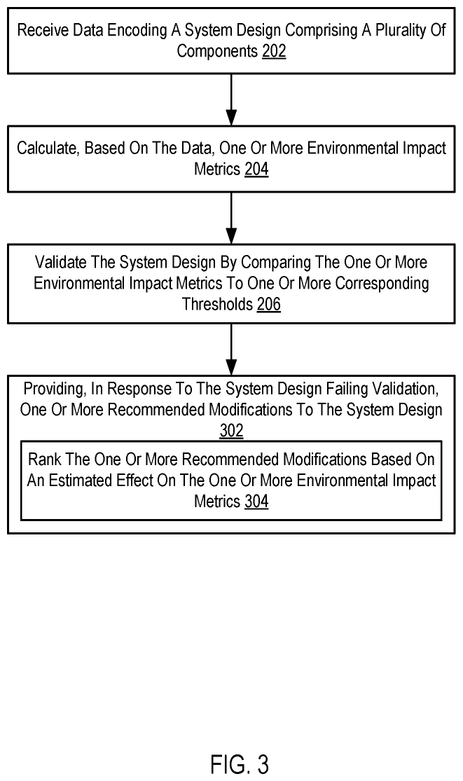

For further explanation, FIG. 3 sets forth a flowchart of another example method of hardware configuration and design based on environmental impact in accordance with some embodiments of the present disclosure. The method of FIG. 3 is similar to FIG. 2 in that the method of FIG. 3 also includes: receiving 202 data encoding a system design comprising a plurality of components; calculating 204, based on the data, one or more environmental impact metrics; and validating 206 the system design by comparing the one or more environmental impact metrics to one or more corresponding thresholds.

The method of FIG. 3 differs from FIG. 2 in that the method of FIG. 3 also includes providing 302, in response to the system design failing validation, one or more recommended modifications to the system design. In some embodiments, the one or more recommended modifications may include modifications that, if implemented, may cause the system design to pass validation. For example, where a particular component has an associated environmental impact metric exceeding the corresponding threshold, the one or more recommended modifications may include a modification to that particular component that would reduce the environmental impact below the threshold. In some embodiments, the one or more recommended modifications may include modifications that may reduce an environmental impact metric without necessarily causing that environmental impact metric to fall below its corresponding threshold. In some embodiments, the one or more recommended modifications may include a combination of modifications (e.g., multiple modifications to one or more components) that, if implemented, may cause the system design to pass validation and/or reduce the degree to which the system design fails validation. The one or more recommended modifications may include, for example, rearranging the layout of components (e.g., rearranging the layout of functional electrical components on a printed circuit board (PCB), replacing some components with different, functionally equivalent or comparable components (e.g., replacing a processor with a voltage regulator), or other modifications as can be appreciated.

In some embodiments, providing 302 the one or more recommended modifications may include performing a dimensionality reduction (principal component analysis (PCA)) to map particular components to their magnitude of contribution to the environmental impact metrics. Thus, the particular components that more significantly affect the environmental impact metrics may be more preferentially recommended for modification where possible. In some embodiments, the dimensionality reduction may be used to establish a ratio of coefficients between embodied emissions from material selection and geographic location of materials and the estimated emissions from use to calculate estimated environmental impact metrics of different recommended modifications. In some embodiments, this may be used to provide a visual cue via an interface to particular users to illustrate the prioritization and reprioritization of the system and component limits.

In some embodiments, these estimated environmental impact metrics may be used, for example, to estimate whether the system, after implementing a particular modification, will cause the system design to pass validation. In some embodiments, these estimated environmental impact metrics may be used to rank the recommended modifications when presented to a user. Accordingly, in some embodiments, providing 302 the one or more recommended modifications may include ranking 304 the one or more recommended modifications based on an estimated effect on the one or more environmental impact metrics. In some embodiments, selection of a particular recommended modification may cause the system design to be updated to reflect the selected recommended modification.

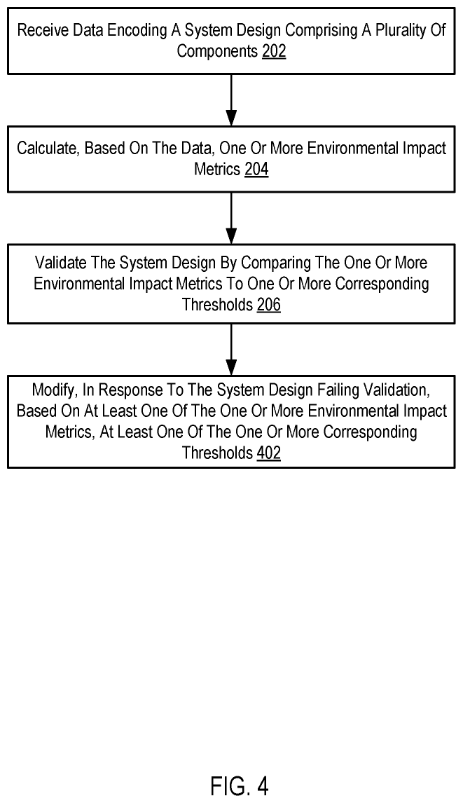

For further explanation, FIG. 4 sets forth a flowchart of another example method of hardware configuration and design based on environmental impact in accordance with some embodiments of the present disclosure. The method of FIG. 4 is similar to FIG. 2 in that the method of FIG. 4 also includes: receiving 202 data encoding a system design comprising a plurality of components; calculating 204, based on the data, one or more environmental impact metrics; and validating 206 the system design by comparing the one or more environmental impact metrics to one or more corresponding thresholds.

The method of FIG. 4 differs from FIG. 2 in that the method of FIG. 4 also includes modifying 402, in response to the system design failing validation, based on at least one of the one or more environmental impact metrics, at least one of the one or more corresponding thresholds. In some embodiments, modifying 402 the at least one of the one or more corresponding thresholds may include modifying one or more per-component thresholds while maintaining a per-system threshold. That is, in some embodiments, limitations on individual system design components may be modified while the limits on the system design as a whole may be maintained.

In some embodiments, modifying 402 at least one of the corresponding one or more thresholds may include selecting one or more of the per-component thresholds to reduce. In some embodiments, the one or more per-component thresholds to reduce may be selected based on a degree to which their respective environmental impact metric falls below the corresponding per-component threshold. In other words, the one or more per-component thresholds may be selected as having a largest buffer between the environmental impact metric and the corresponding per-component threshold. In some embodiments, the one or more per-component thresholds may be selected where their buffer (e.g., the difference between the environmental impact metric and the threshold) exceeds some threshold amount or some threshold level of deviation. In some embodiments, the one or more per-component thresholds may be selected as having the highest buffer relative to other components.

In some embodiments, the amount by which the one or more per-component thresholds are reduced may be calculated according to a variety of approaches. For example, in some embodiments, the amount may be calculated such that the modified threshold preserves a predefined amount of buffer between the modified threshold and the corresponding environmental impact metric. In some embodiments, the amount may be calculated so as to not exceed some degree of modification or deviation. Other approaches may also be used to calculate the amount by which the one or more per-component thresholds are reduced.

In some embodiments, modifying 402 at least one of the corresponding one or more thresholds may include selecting one or more of the per-component thresholds to increase. In some embodiments, the one or more per-component thresholds to increase may be selected where their respective environmental impact metrics exceed the corresponding per-component threshold (e.g., causing validation to fail). In some embodiments, the one or more per-component thresholds to increase may be selected where their respective buffer falls below some other threshold amount.

In some embodiments, the amount by which the one or more per-component thresholds are increased may be calculated according to a variety of approaches. For example, in some embodiments, the amount may be calculated such that the modified threshold exceeds the corresponding environmental impact metric or exceeds the corresponding environmental impact by some other threshold amount. In some embodiments, the amount may be calculated so as to not exceed some degree of modification or deviation (e.g., deviation from a voluntary environmental country specification). Other approaches may also be used to calculate the amount by which the one or more per-component thresholds are increased.

In some embodiments, various restrictions or limitations may dictate which thresholds can be modified and/or amounts by which these thresholds may be modified. For example, in some embodiments, one or more of the per-component thresholds may be restricted from any modification. As another example, in some embodiments, one or more of the per-component thresholds may be restricted so as to allow only increasing or decreasing but not both. In some embodiments, restrictions may dictate amounts by which particular thresholds may be increased or decreased.

In some embodiments, one or more notifications or messages may be generated and sent indicating that the thresholds were modified. For example, notifications or messages may be sent to other team members, chief engineers, and the like. In some embodiments, modification of these thresholds may require third-party approval. For example, modification of these thresholds may require approval of a team lead or chief engineer. Accordingly, in some embodiments, a notification or message soliciting approval may be sent to the appropriate user in response to an attempt to modify these thresholds. In such embodiments, such thresholds may be modified in response to receiving approval from the third party. In some embodiments, increasing one threshold may necessitate decreasing another threshold. A notification may be sent out (e.g., through the CAD software) to the designer of another component within the same end-system that design changes are required to get under the new lower threshold for their design if the decreasing of the threshold causes their component to now fail the new lower threshold. For example, if someone designing a processor drawer goes over their threshold, another designer working on an IO drawer may be notified that their design must change to allow the processor drawer to use a new higher threshold. Alternatively, selections made during the design of one product may yield suggestions for improvement or changes to another product even if a threshold was not exceeded. A better environmental footprint may be achieved if the same materials from the same factory are used across two components of an end system. If a design choice is made on a processor drawer, a notification may be sent to the designer of an IO drawer to make a change that will improve the end products overall environmental footprint.

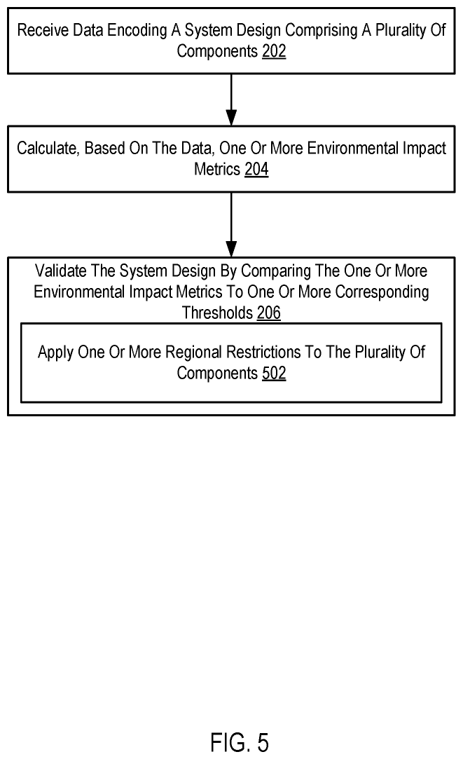

For further explanation, FIG. 5 sets forth a flowchart of another example method of hardware configuration and design based on environmental impact in accordance with some embodiments of the present disclosure. The method of FIG. 5 is similar to FIG. 2 in that the method of FIG. 5 also includes: receiving 202 data encoding a system design comprising a plurality of components; calculating 204, based on the data, one or more environmental impact metrics; and validating 206 the system design by comparing the one or more environmental impact metrics to one or more corresponding thresholds.

The method of FIG. 5 differs from FIG. 2 in that validating 206 the system design by comparing the one or more environmental impact metrics to one or more corresponding thresholds comprises applying 502 one or more regional restrictions to the plurality of components. In some embodiments, data may indicate regions (e.g., countries, cities, continents, and the like) from which particular components may be sourced. Where a particular component can be sourced from multiple regions, a user may select (e.g., via the design software) a particular region from which a particular component should be sourced for the purposes of validation. Accordingly, the one or more regional restrictions may indicate, for example, that components should not be acquired from a particular region, a threshold amount or ratio of components that may be acquired from a particular region, that components having certain materials should not be acquired from a particular region, and the like. Such regional restrictions may be based on various regulatory requirements, financial considerations, trade relationships, business presence requirements, and the like.

Accordingly, in some embodiments, the system design may fail validation where the one or more regional restrictions are violated. In some embodiments, where a regional restriction prevents use of components or a class of components from a particular region, the design software may enforce this restriction by preventing these components from ever being added to the system design. For example, libraries of components that may be selected for inclusion in a system design may exclude components from these regions. Thus, rather than allow the components to be added and have validation ultimately fail, this approach preemptively excludes components that may violate regional restrictions from being added to a system design under development.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
receiving data encoding a system design comprising a plurality of components;
calculating, based on the data, one or more environmental impact metrics; and
validating the system design by comparing the one or more environmental impact metrics to one or more corresponding thresholds.

2. The method of claim 1, wherein the one or more environmental impact metrics comprise a total environmental impact metric for the system design and wherein the one or more corresponding thresholds comprise a total environmental impact threshold.

3. The method of claim 2, wherein the one or more environmental impact metrics comprise a plurality of component environmental impact metrics and wherein the one or more corresponding thresholds comprise a plurality of component environmental impact thresholds.

4. The method of claim 1, wherein the one or more environmental impact metrics are based on one or more mechanical contributions and one or more electrical contributions.

5. The method of claim 1, further comprising providing, in response to the system design failing validation, one or more recommended modifications to the system design.

6. The method of claim 5, wherein providing the one or more recommended modifications further comprises ranking the one or more recommended modifications based on an estimated effect on the one or more environmental impact metrics.

7. The method of claim 6, wherein ranking the one or more recommended modifications is based on a principal component analysis dimensionality reduction of the one or more environmental impact metrics.

8. The method of claim 1, further comprising modifying, in response to the system design failing validation, based on at least one of the one or more environmental impact metrics, at least one of the one or more corresponding thresholds.

9. The method of claim 1, wherein validating the system design further comprises applying one or more regional restrictions to the plurality of components.

10. An apparatus comprising:
a processing device; and
memory operatively coupled to the processing device, wherein the memory stores computer program instructions that, when executed, cause the processing device to:
receive data encoding a system design comprising a plurality of components;
calculate, based on the data, one or more environmental impact metrics; and
validate the system design by comparing the one or more environmental impact metrics to one or more corresponding thresholds.

11. The apparatus of claim 10, wherein the one or more environmental impact metrics comprise a total environmental impact metric for the system design and wherein the one or more corresponding thresholds comprise a total environmental impact threshold.

12. The apparatus of claim 11, wherein the one or more environmental impact metrics comprise a plurality of component environmental impact metrics and wherein the one or more corresponding thresholds comprise a plurality of component environmental impact thresholds.

13. The apparatus of claim 10, wherein the one or more environmental impact metrics are based on one or more mechanical contributions and one or more electrical contributions.

14. The apparatus of claim 10, wherein the instructions, when executed, further cause the processing device to provide, in response to the system design failing validation, one or more recommended modifications to the system design.

15. The apparatus of claim 14, wherein, to provide the one or more recommended modifications, the instructions, when executed, further cause the processing device to rank the one or more recommended modifications based on an estimated effect on the one or more environmental impact metrics.

16. The apparatus of claim 15, wherein ranking the one or more recommended modifications is based on a dimensionality reduction of the one or more environmental impact metrics.

17. The apparatus of claim 10, wherein the instructions, when executed, further cause the processing device to modify, in response to the system design failing validation, based on at least one of the one or more environmental impact metrics, at least one of the one or more corresponding thresholds.

18. The apparatus of claim 10, wherein, to validate the system design, the instructions, when executed, further cause the processing device to apply one or more regional restrictions to the plurality of components.

19. A computer program product comprising a computer readable storage medium, wherein the computer readable storage medium comprises computer program instructions that, when executed:
receive data encoding a system design comprising a plurality of components;
calculate, based on the data, one or more environmental impact metrics; and
validate the system design by comparing the one or more environmental impact metrics to one or more corresponding thresholds.

20. The computer program product of claim 19, wherein the one or more environmental impact metrics comprise a total environmental impact metric for the system design and wherein the one or more corresponding thresholds comprise a total environmental impact threshold.

21. The computer program product of claim 20, wherein the one or more environmental impact metrics comprise a plurality of component environmental impact metrics and wherein the one or more corresponding thresholds comprise a plurality of component environmental impact thresholds.

22. The computer program product of claim 19, wherein the one or more environmental impact metrics are based on one or more mechanical contributions and one or more electrical contributions.

23. The computer program product of claim 19, wherein the instructions, when executed, further cause the processing device to provide, in response to the system design failing validation, one or more recommended modifications to the system design.

24. The computer program product of claim 19, wherein, to provide the one or more recommended modifications, the instructions, when executed, rank the one or more recommended modifications based on an estimated effect on the one or more environmental impact metrics.

25. The apparatus of claim 15, wherein ranking the one or more recommended modifications is based on a dimensionality reduction of the one or more environmental impact metrics.
